(19) United States
(12) Patent Application Publication
(10) Pub. No.: US 2026/0059830 A1
(43) Pub. Date: Feb. 26, 2026

(54) FORK SHEET FIELD EFFECT TRANSISTOR WITH INCREASED ELECTROSTATIC CONTROL

(71) Applicant: International Business Machines Corporation, Armonk, NY (US)

(72) Inventors: Shay Reboh, Guilderland, NY (US); Debarghya Sarkar, Latham, NY (US); Ruilong Xie, Niskayuna, NY (US); James Patrick Mazza, Saratoga Springs, NY (US)

(21) Appl. No.: 18/815,131

(22) Filed: Aug. 26, 2024

(51) Int. Cl. H01L 29/66; H01L 21/762; H01L 27/092; H01L 29/06; H01L 29/423; H01L 29/775; H01L 29/786

(52) U.S. Cl. CPC H10D 64/018; H01L 21/76224; H10D 30/43; H10D 30/6735; H10D 30/6757; H10D 62/121; H10D 84/85; H10D 30/014

(57) ABSTRACT

A semiconductor device is provided which includes a pair of fork sheet transistors. Each fork sheet transistor includes a plurality of vertically stacked, spaced apart semiconductor material nanosheets and a gate all around (GAA) structure formed on the semiconductor material nanosheets. The semiconductor device also includes a dielectric pillar, composed of a first dielectric material and located between the pair of fork sheet transistors. The semiconductor device further includes: first inner spacer portions, composed of a second dielectric material, located between the dielectric pillar and inner edges of the semiconductor material nanosheets of each fork sheet transistor; and second inner spacer portions, composed of the second dielectric material, and located between each of the semiconductor material nanosheets, above the semiconductor material nanosheets and below the semiconductor material nanosheets.

### BACKGROUND

The present application relates to semiconductor technology, and more particularly to a semiconductor device including pairs of fork sheet transistors with a dielectric wall structure in between each pair of fork sheet transistors and dielectric inner spacer portions, located between semiconductor material nanosheets of the fork sheet transistors and the dielectric wall structure, above the semiconductor material nanosheets and below the semiconductor material nanosheets to provide increased electrostatic control of the fork sheet transistors.

A fork sheet transistor is a type of transistor that is being currently developed for 2 nm nodes and beyond. The fork sheet transistor is an extension of a nanosheet transistor, where the nanosheets are controlled by a tri-gate forked structure, which is achieved by introducing a dielectric wall structure (i.e., dielectric pillar) between the p-type field effect transistor (PFET) and the n-type field effect transistor (NFET). This isolation allows for tighter n-to-p spacing, reduction of effective cell height and higher performance. In fork sheet devices, both the NFET and PFET are integrated in the same structure, unlike existing gate-all-around (GAA) FETs that use different devices for the NFETs and PFETs.

### SUMMARY

A semiconductor device is provided which includes a pair of fork sheet transistors. Each fork sheet transistor includes a plurality of vertically stacked, spaced apart semiconductor material nanosheets and a gate all around structure formed on the semiconductor material nanosheets. The semiconductor device also includes a dielectric pillar, composed of a first dielectric material and located between the pair of fork sheet transistors. The semiconductor device further includes: first inner spacer portions, composed of a second dielectric material, located between the dielectric pillar and inner edges of the semiconductor material nanosheets of each fork sheet transistor; and second inner spacer portions, composed of the second dielectric material, and located between each of the semiconductor material nanosheets, above the semiconductor material nanosheets and below the semiconductor material nanosheets.

In one aspect of the present application, a semiconductor device is provided that includes a substrate and a pair of fork sheet transistors formed on the substrate. Each fork sheet transistor includes a semiconductor channel region including a plurality of vertically stacked, and spaced apart semiconductor material nanosheets. The semiconductor device also includes a dielectric pillar, composed of a first dielectric material, and located between the pair of fork sheet transistors. The semiconductor device further includes first inner spacer portions, composed of a second dielectric material, located between the dielectric pillar and each semiconductor channel region and second inner spacer portions, composed of the second dielectric material, located between each of the semiconductor material nanosheets, above each semiconductor channel region and below each semiconductor channel region.

In another aspect of the present application, a fork sheet transistor is provided that includes a source region, a drain region and a semiconductor channel region. The semiconductor channel region includes a plurality of semiconductor material nanosheets, separated from each other, and stacked vertically between the source region and the drain region. The fork sheet transistor also includes a gate all around structure formed on the plurality of semiconductor material nanosheets. First inner spacer portions, composed of a first dielectric material, are located between an edge of the semiconductor channel region and a dielectric pillar. The dielectric pillar is composed of a second dielectric material and is located adjacent the semiconductor channel region. Second inner spacer portions, composed of the second dielectric material, are located between each of the plurality of semiconductor material nanosheets, above the semiconductor channel region and below the semiconductor channel region.

### BRIEF DESCRIPTION OF THE DRAWINGS

FIG. 1 is a top down view of a device layout that can be used in accordance with an embodiment of the present application.

FIG. 2A illustrates a cross sectional view of an exemplary structure, through cut B-B along an edge of a gate structure of the device layout in FIG. 1, that can be used in accordance with an embodiment of the present application, the exemplary structure including inner spacer portions, composed of a dielectric material, located between a dielectric pillar and inner edges of semiconductor material nanosheets of each semiconductor material channel region, between each of the semiconductor material nanosheets, above each semiconductor channel region and below each semiconductor channel region.

FIG. 2B illustrates a cross sectional view of an exemplary structure, through cut A-A along a middle portion of the gate structure shown in FIG. 1, that can be used in accordance with an embodiment of the present application, the exemplary structure in FIG. 2B illustrating a gate all around structure formed on 4 sides of the transistors shown in FIG. 2A.

FIG. 3A illustrates a cross sectional view of an exemplary structure, through cut B-B or cut A-A of the device layout in FIG. 1, prior to a fin patterning stage of a fabrication process for forming the exemplary structure shown in FIG. 2A and FIG. 2B.

FIG. 3B illustrates a cross sectional view of an exemplary structure, through cut B-B or cut A-A of the device layout in FIG. 1, after the fin patterning stage of the fabrication process for forming the exemplary structure shown in FIG. 2A and FIG. 2B.

FIG. 4A illustrates a cross sectional view of an exemplary structure, through cut B-B of the device layout in FIG. 1, during a first part of a shallow trench isolation forming stage of the fabrication process for forming the exemplary structure shown in FIG. 2A and FIG. 2B.

FIG. 4B illustrates a cross sectional view of an exemplary structure, through cut B-B or cut A-A of the device layout in FIG. 1, during a second part of the shallow trench isolation forming stage of the fabrication process for forming the exemplary structure shown in FIG. 2A and FIG. 2B.

FIG. 5 illustrates a cross sectional view of an exemplary structure, through cut B-B or cut A-A of the device layout in FIG. 1, after a first dielectric layer deposition stage of the fabrication process for forming the exemplary structure shown in FIG. 2A and FIG. 2B.

FIG. 6 illustrates a cross sectional view of an exemplary structure, through cut B-B or cut A-A of the device layout in FIG. 1, after a second dielectric layer deposition stage of the fabrication process for forming the exemplary structure shown in FIG. 2A and FIG. 2B.

FIG. 7 illustrates a cross sectional view of an exemplary structure, through cut B-B or cut A-A of the device layout in FIG. 1, after a first dielectric layer etching stage of the fabrication process for forming the exemplary structure shown in FIG. 2A and FIG. 2B.

FIG. 8 illustrates a cross sectional view of an exemplary structure, through cut B-B or cut A-A of the device layout in FIG. 1, after a second dielectric layer etching stage of the fabrication process for forming the exemplary structure shown in FIG. 2A and FIG. 2B.

FIG. 9 illustrates a cross sectional view of an exemplary structure, through cut B-B or cut A-A of the device layout in FIG. 1, after performing a gate enabling oxide layer deposition stage of the fabrication process for forming the exemplary structure shown in FIG. 2A and FIG. 2B.

FIG. 10A illustrates a cross sectional view of an exemplary structure, through cut B-B of the device layout in FIG. 1, prior to performing a sacrificial semiconductor material indenting stage of the fabrication process for forming the exemplary structure shown in FIG. 2A and FIG. 2B.

FIG. 10B illustrates a cross sectional view of an exemplary structure, through cut A-A of the device layout in FIG. 1, prior to performing the sacrificial semiconductor material indenting stage of the fabrication process for forming the exemplary structure shown in FIG. 2A and FIG. 2B.

FIG. 11A illustrates a cross sectional view of an exemplary structure, through cut B-B of the device layout in FIG. 1, after performing the sacrificial semiconductor material indenting stage of the fabrication process for forming the exemplary structure shown in FIG. 2A and FIG. 2B.

FIG. 11B illustrates a cross sectional view of an exemplary structure, through cut A-A of the device layout in FIG. 1, after performing the sacrificial semiconductor material indenting stage of the fabrication process for forming the exemplary structure shown in FIG. 2A and FIG. 2B.

FIG. 12A illustrates a cross sectional view of an exemplary structure, through cut B-B of the device layout in FIG. 1, after performing an inner spacer portion deposition stage of the fabrication process for forming the exemplary structure shown in FIG. 2A and FIG. 2B.

FIG. 12B illustrates a cross sectional view of an exemplary structure, through cut A-A of the device layout in FIG. 1, after performing the inner spacer portion deposition stage of the fabrication process for forming the exemplary structure shown in FIG. 2A and FIG. 2B.

FIG. 13 illustrates a cross sectional view of an exemplary structure, through a cut, parallel to but to the right of the cut B-B of the device layout in FIG. 1, along an edge of the middle gate spacer of the gate structure shown in FIG. 1, after performing an epitaxy growth stage of the fabrication process for forming the exemplary structure shown in FIG. 2A and FIG. 2B.

FIG. 14 illustrates a cross sectional view of an exemplary structure, through cut A-A of the device layout in FIG. 1, after performing a dummy gate etching stage of the fabrication process for forming the exemplary structure shown in FIG. 2A and FIG. 2B.

FIG. 15 illustrates a cross sectional view of an exemplary structure, through cut A-A of the device layout in FIG. 1, after performing a gate enabling oxide layer etching stage of the fabrication process for forming the exemplary structure shown in FIG. 2A and FIG. 2B.

FIG. 16 illustrates a cross sectional view of an exemplary structure, through cut A-A of the device layout in FIG. 1, after performing the sacrificial semiconductor material etching stage of the fabrication process for forming the exemplary structure shown in FIG. 2A and FIG. 2B.

FIG. 17 illustrates a cross sectional view of an exemplary structure, through cut A-A along a middle portion of the gate structure shown in FIG. 1, after performing a first dielectric layer etching stage of the fabrication process for forming the exemplary structure shown in FIG. 2A and FIG. 2B.

FIG. 18 illustrates a cross sectional view of an exemplary structure, through cut A-A along the middle portion of the gate structure shown in FIG. 1, after performing a high-k deposition stage of the fabrication process for forming the exemplary structure shown in FIG. 2A and FIG. 2B.

FIG. 19 illustrates a cross sectional view of an exemplary structure, through cut A-A along the middle portion of the gate structure shown in FIG. 1, that can be used in accordance with an embodiment of the present application, the exemplary structure in FIG. 19 illustrating a gate all around structure formed on 4 sides of the transistors shown in FIG. 2A.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region.

Nanosheet transistors facilitate an increase in the effective channel width and provide considerable scaling with high drive current capability, less leakage and reduced power consumption. Nanosheet transistors provide a larger drive current for a given footprint compared to finFET technology. In other words, nanosheet transistors provide a reduce device footprint while improving overall performance (e.g., cost).

Conventional GAA nanosheet structures allow the semiconductor material nanosheets to be electrostatically controlled, by the gate, on 4 sides of the transistor. However, because the semiconductor material nanosheets of conventional fork sheet transistors are isolated from each other by the dielectric pillar, the tri-gate structure of conventional fork sheet transistors has less electrostatic control of the semiconductor material nanosheets than GAA structures due to weaker electrostatic control of portions of the semiconductor material nanosheets closer to the dielectric pillar. In addition, the gate stack passes under a space between edges of the semiconductor channel regions and the gate-cut structure and directly touches a source/drain region of the fork sheet transistor, which generates an undesirable capacitance penalty. Further, during etching of the fork sheet transistors, a hole is formed which creates a path to the source/drain region. However, when semiconductor material (e.g., silicon germanium (SiGe)) is removed, a source/drain region (e.g., an SiGe source/drain region) may be undesirably etched away.

Embodiments of the present application provide a semiconductor device which exploits the advantages of the GAA nanosheet structure (e.g., increased electrostatic control, by the gate, on 4 sides of the transistor) as well as the advantages (e.g., tighter n-to-p spacing, reduction of effective cell height and higher performance) afforded by fork sheet transistors. For example, as described in more detail below, embodiments of the present application provide a semiconductor device in which each pair of fork sheet transistors include first inner spacer portions, composed of a second dielectric material, located between the dielectric pillar and inner edges of the semiconductor material nanosheets of each fork sheet transistor and second inner spacer portions, composed of the second dielectric material, located between each of the semiconductor material nanosheets, above the semiconductor material nanosheets and below the semiconductor material nanosheets. The vertical and horizontal inner spacer portions provide increased electrostatic control of portions of the semiconductor material nanosheets in the middle regions of the gate structures such that the gate structures have increased electrostatic control of the semiconductor material nanosheets. The vertical and horizontal inner spacer portions also avoid a capacitance penalty by preventing gate structures from passing under a space between edges of semiconductor channel regions and the dielectric pillar and from directedly touching the source/drain region. In addition, the vertical and horizontal inner spacer portions prevent portions of the source/drain region from being substantially etched away.

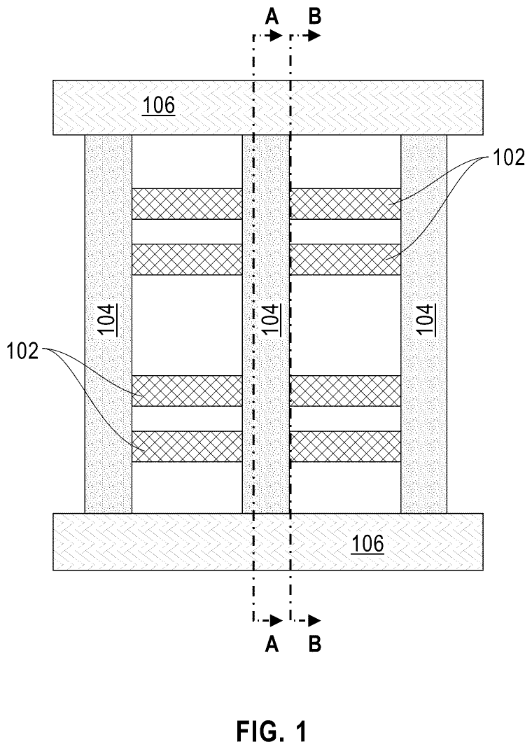

Referring first to FIG. 1, there is illustrated a top down view of a device layout, representing a portion of a semiconductor device, which can be employed in accordance with an embodiment of the present application. The illustrated device layout includes active areas 102. The device layout shown in FIG. 1 also includes gate structures (also known as gate lines) 104 used to form the gate structure and gate-cut structures 106 used to cut or separate the gate structures formed throughout the semiconductor device.

The gate structures 104 include a gate dielectric material and a gate electrode, both of which are not separately shown, but intended to be within the region defined by the gate structures 104. As is known to those skilled in the art, a gate dielectric material directly contacts a physically exposed surface(s) of the semiconductor channel region, and a gate electrode is formed on the gate dielectric material. The gate dielectric material typically has a dielectric constant in a range of about 18 to about 25. Illustrative examples of gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material can further include dopants such as lanthanum (La), aluminum (Al) and/or magnesium (Mg). The gate electrode can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the semiconductor channel regions of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co). The gate structure 104 can be formed by deposition, followed by a planarization process.

The gate structures 104 shown in FIG. 1 include gate spacer portions (also referred to herein as gate spacers) and dummy gate portions (also referred to herein as dummy gates). Gate spacers are located toward the left and right edges of each of the gate structures 104 shown in FIG. 1, while the dummy gates are formed at a middle portion, between the gate spacers, of each of the gate structures 104 shown in FIG. 1.

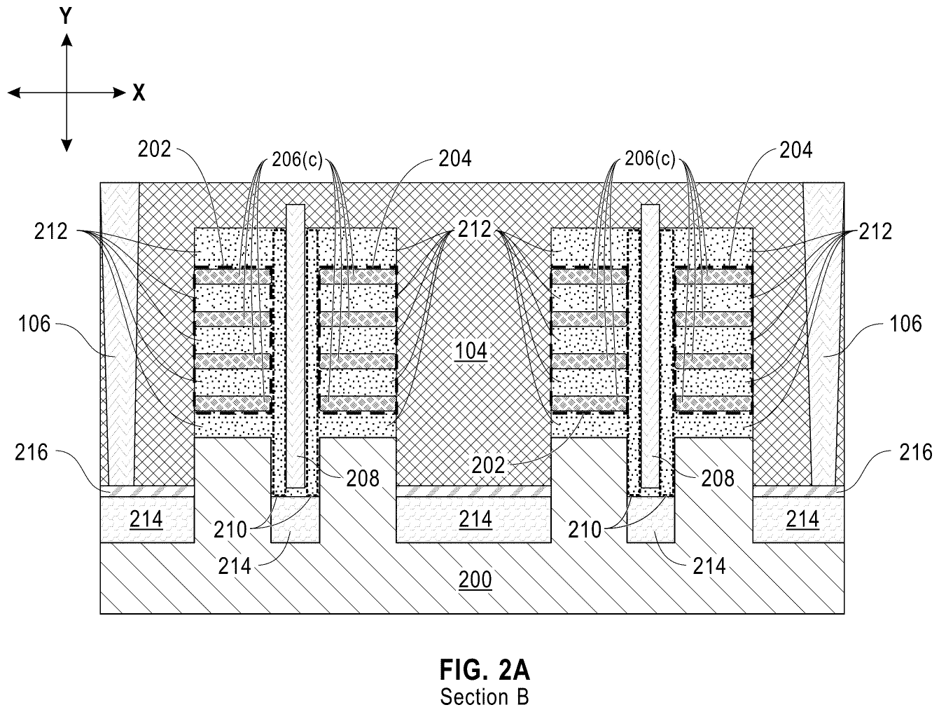

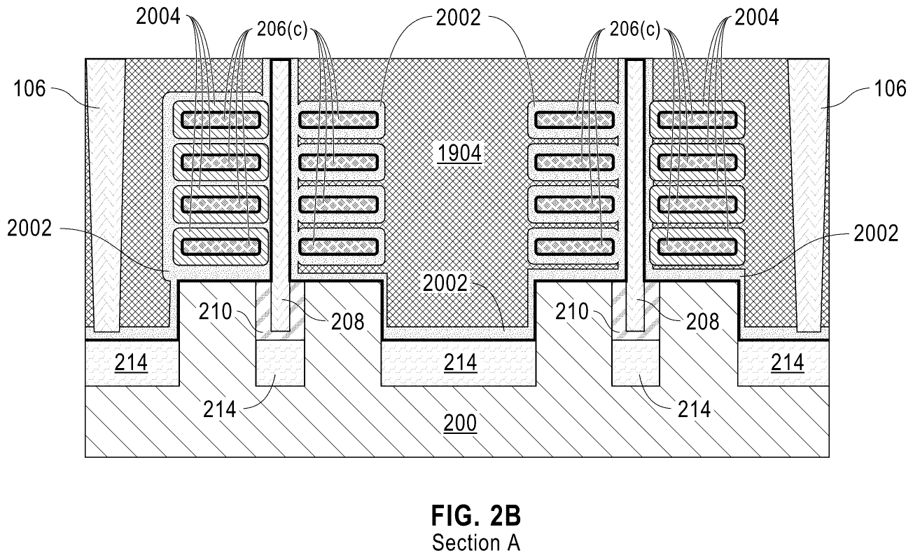

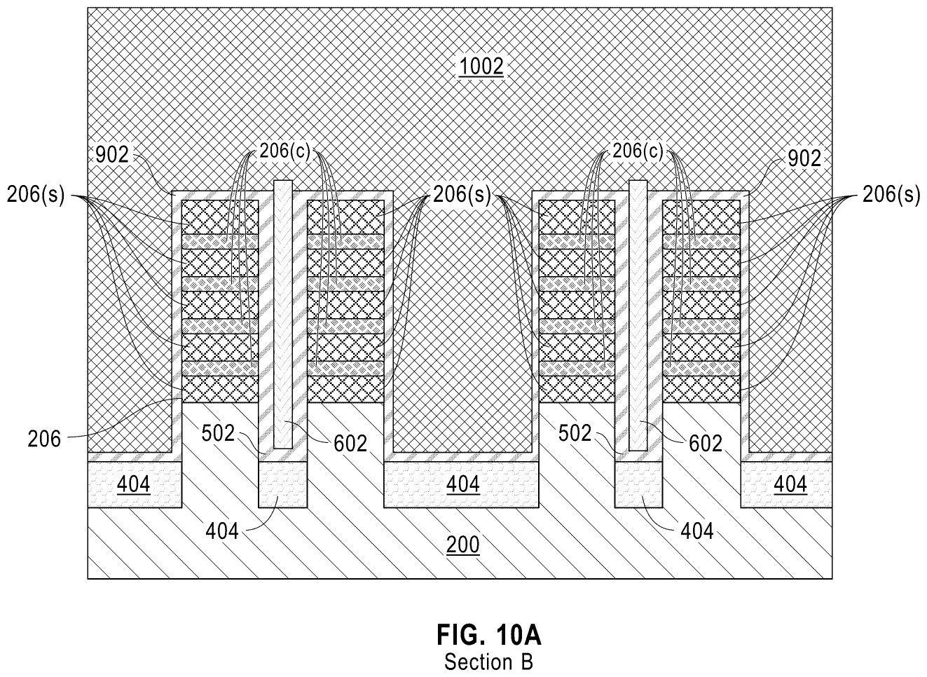

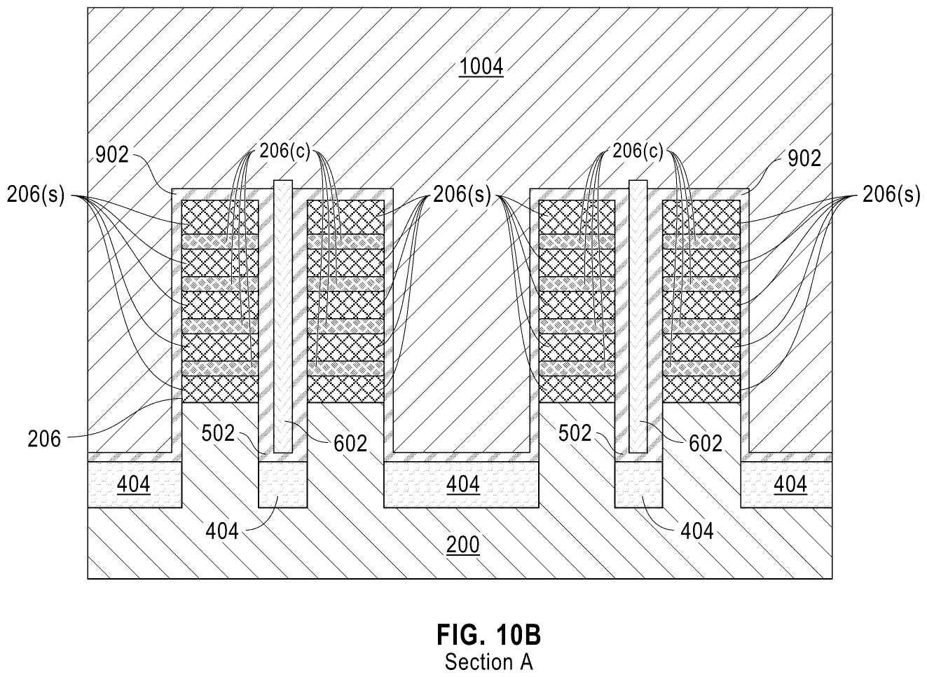

FIG. 2A illustrates a cross sectional view of an exemplary structure, through cut B-B along an edge (i.e., along a gate spacer) of the gate structure 104 shown in the device layout in FIG. 1, that can be used in accordance with an embodiment of the present application. That is, the gate structure 104 in FIG. 2A corresponds to a gate spacer of the gate structure 104 (shown as gate spacer 1002 in FIGS. 10A, 11A, 12A and 13). FIG. 2B illustrates a cross sectional view of an exemplary structure, through cut A-A along a middle portion (i.e., along a dummy gate) of the gate structure 104 shown in FIG. 1, that can be used in accordance with an embodiment of the present application. That is, FIG. 2A illustrates a cross sectional view of a portion of a fabricated semiconductor device along a gate spacer of the gate structure 104 shown in FIG. 1 while FIG. 2A illustrates a cross sectional view of the same portion of the fabricated semiconductor device shown in FIG. 2A, but along a dummy gate of the gate structure 104 shown in FIG. 1.

As shown in FIG. 2A, the exemplary structure includes a substrate 200 and two pairs of fork sheet transistors. Each fork sheet transistor includes a vertical stack of spaced apart semiconductor material nanosheets 206(c) as a semiconductor channel region 202 or 204. The exemplary structure also includes a shallow trench isolation (STI) layer 214, a gate enabling dielectric layer 216 (e.g., an oxide layer), a portion of the gate structure 104 shown in the middle of the device layout in FIG. 1 and portions of the gate-cut structures 106 shown in FIG. 1.

The substrate 200 includes at least a semiconductor device layer composed of a semiconductor material. Although not shown, in addition to the semiconductor device layer, the substrate 200 can also include a semiconductor base layer composed of a semiconductor material different from the semiconductor material of the semiconductor device layer and/or an etch stop layer between the semiconductor base layer and the semiconductor device layer. As used throughout the present application, the term “semiconductor material” denotes a material that has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. If present, the etch stop layer can be composed of a dielectric material such as, for example, silicon dioxide and/or boron nitride or a semiconductor material that is compositionally different from semiconductor device layer and, if present, the semiconductor base layer.

In an embodiment, the semiconductor material nanosheets of adjacent semiconductor channel regions of a pair of fork sheet transistors are used for providing different conductivity types of transistors. For example, the semiconductor material nanosheets of one of the semiconductor channel regions (e.g., semiconductor channel region 202) can provide high channel mobility for NFET devices and the semiconductor material nanosheets of an adjacent semiconductor channel region (e.g., semiconductor channel region 204) can provide high channel mobility for PFET devices. In another embodiment, the semiconductor material nanosheets of adjacent semiconductor channel regions of a pair of fork sheet transistors are used for providing the same conductivity type transistors. For example, the semiconductor material nanosheets of both of the semiconductor channel regions 202 and 204 are used in providing NFETs. In yet another example, the semiconductor material nanosheets of both of the semiconductor channel regions 202 and 204 are used in providing PFETs.

For simplification purposes, the exemplary structure in FIG. 2A shows two pairs of fork sheet transistors (i.e., two pairs of adjacent first and second semiconductor channel regions 202 and 204) with each of the semiconductor channel regions 202 and 204 including 4 layers of vertically stacked, spaced apart semiconductor channel material nanosheets 206(c). The number of fork sheet transistors and the number of layers of vertically stacked semiconductor material nanosheets in each semiconductor channel region shown in FIG. 2A is merely an example. Embodiments of the present application can include semiconductor devices having any number of fork sheet transistors as well as a number of layers of vertically stacked semiconductor material nanosheets different from the number of layers of vertically stacked semiconductor material nanosheets shown in FIG. 2A.

The exemplary structure shown in FIG. 2A also includes, for each pair of fork sheet transistors (i.e., for each pair of adjacent semiconductor channel regions 202 and 204), a dielectric pillar 208, including a first dielectric material, located between and separating each pair of fork sheet transistors from each other. The exemplary structure shown in FIG. 2A also includes, for each pair of fork sheet transistors, inner spacer portions which include first inner spacer portions 210 (referred to hereinafter as “vertical inner spacer portions”) and second inner spacer portions 212 (referred to hereinafter as “horizontal inner spacer portions”). The second inner portions 212 can include first horizontal spacer portions, extending in a horizontal direction perpendicular to the inner edges of the dielectric pillar, and located between each of the semiconductor material nanosheets, a second horizontal spacer portion, extending in the horizontal direction, and located above a top one of the semiconductor material nanosheets, and a third horizontal spacer portion, extending in the horizontal direction, and located below a bottom one of the semiconductor material nanosheets.

The vertical and horizontal inner spacer portions 210 and 212 are composed of a second dielectric material. In an example, the dielectric pillars 208 (composed of the first dielectric material) have the same composition as the vertical and horizontal inner spacer portions 210 and 212 (composed of the second dielectric material). Alternatively, the dielectric pillars 208 have a different composition than the vertical and horizontal inner spacer portions 210 and 212.

The vertical inner spacer portions 210 extend in a vertical direction (i.e., the Y direction shown in FIG. 2A) parallel to the inner edges of the dielectric pillar, from the STI) layer 214 and are located between the dielectric pillar 208 and inner edges of the adjacent semiconductor channel regions 202 and 204. That is, a first vertical inner spacer portion 210 extends vertically between the dielectric pillar 208 and an inner edge of the first semiconductor channel region 202 (e.g., between inner edges of the vertically stacked semiconductor material nanosheets 206(c) of the first semiconductor channel region 202) and a second vertical inner spacer portion 210 extends vertically between the dielectric pillar 208 and an inner edge of the adjacent second semiconductor channel region 204 (e.g., between inner edges of the vertically stacked semiconductor material nanosheets 206(c) of the second semiconductor channel region 204).

The horizontal inner spacer portions 212 extend horizontally (in the X direction shown in FIG. 2A) between edges of each semiconductor channel region 202 and 204. The horizontal inner spacer portions 212 include portions which are located between the vertically stacked semiconductor material nanosheets 206(c) as well as portions above each semiconductor channel region 202 and 204 (i.e., above the top semiconductor material nanosheet 206(c) in each semiconductor channel region) and below each semiconductor channel region 202 and 204 (i.e., below the bottom semiconductor material nanosheet 206(c) in each semiconductor channel region).

The exemplary structure shown in FIG. 2A illustrates the exploits the advantages of (e.g., tighter n-to-p spacing, reduction of effective cell height and higher performance) afforded by conventional fork sheet transistors while also providing additional advantages over conventional fork sheet transistors. For example, the vertical and horizontal inner spacer portions 210 and 212 described above (e.g., location and composition of the vertical and horizontal inner spacer portions 210 and 212) prevent gate structures from passing under a space between edges of the semiconductor channel regions and the dielectric pillar and directly contacting the source/drain region. Accordingly, an undesirable capacitance penalty is prevented. In addition, the vertical and horizontal inner spacer portions 210 and 212 prevent substantial portions of the source/drain region from being undesirably etched away.

FIG. 2B illustrates a cross sectional view of an exemplary structure, through cut A-A along a middle portion of the gate structure shown in FIG. 1, that can be used in accordance with an embodiment of the present application. The exemplary structure in FIG. 2B illustrates a gate all around structure, formed on 4 sides (i.e., the top, bottom, left and right) of each of the semiconductor material nanosheets 206(c) shown in FIG. 2A, after performing a WFM replacement gate cut forming stage of the fabrication process. That is, while the GAA structure is not shown in the cross sectional view through cut B-B in FIG. 2A, the GAA structure (e.g., WFM replacement gate formed on 4 sides of each of the semiconductor material nanosheets 206(c)) is shown in the cross sectional through cut B-B in FIG. 2B. In the present application, the GAA structure surrounds each of the semiconductor material nanosheets 206(c) (i.e., the plurality of vertically stacked and spaced apart semiconductor nanosheets.

Two different types of WFMs (i.e., different metal compositions) are used in the exemplary structure shown in FIG. 2B. For example, WFM 2002 is formed directly on semiconductor channel material layers of two of the semiconductor channel regions, and WFM 2004 is formed directly on semiconductor channel material layers of two adjacent semiconductor channel regions. In addition, WFM 2004 is formed on WFM 2002 for one of the semiconductor channel regions. The polarity of the material of the WFMs 2002 and 2004 and the metal gate material 1904 are matched to the polarity of the fork sheet transistor.

Accordingly, in addition to the advantages described above with regard to FIG. 2A, the GAA structure illustrated in FIG. 2B provides increased electrostatic control (as compared to conventional tri-gate structures) of portions of the semiconductor material nanosheets in the middle regions of the gate structures such that the gate structures have increased electrostatic control of the semiconductor material nanosheets.

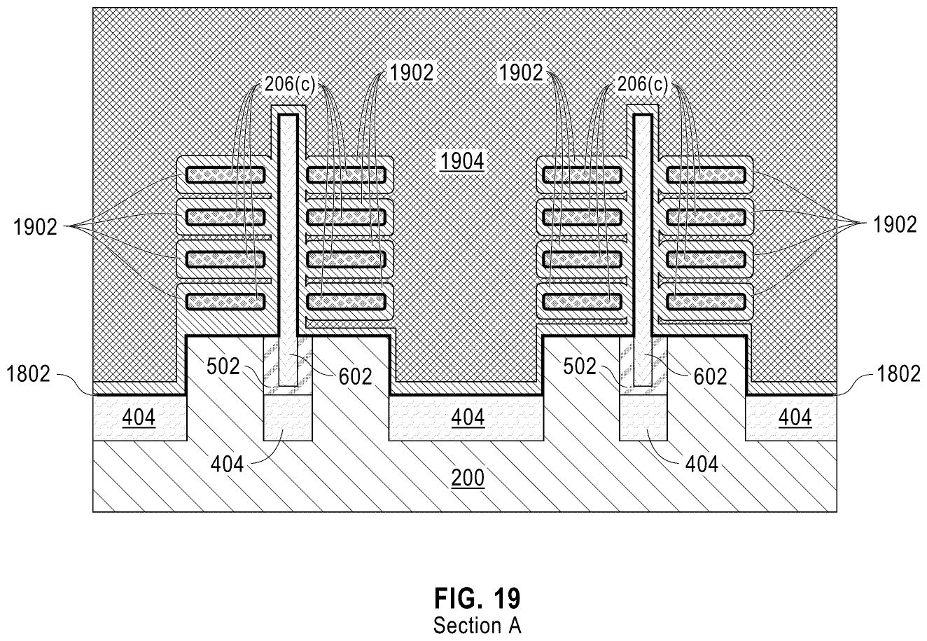

The structure shown in FIG. 2B is merely an example. Features of the present disclosure can include alternative structures (e.g., the structure shown in FIG. 19) any number of different types of WFMs as well as different combinations of WFMs to match the polarity of the material of the WFMs and the metal gate material to the polarity of the fork sheet transistor.

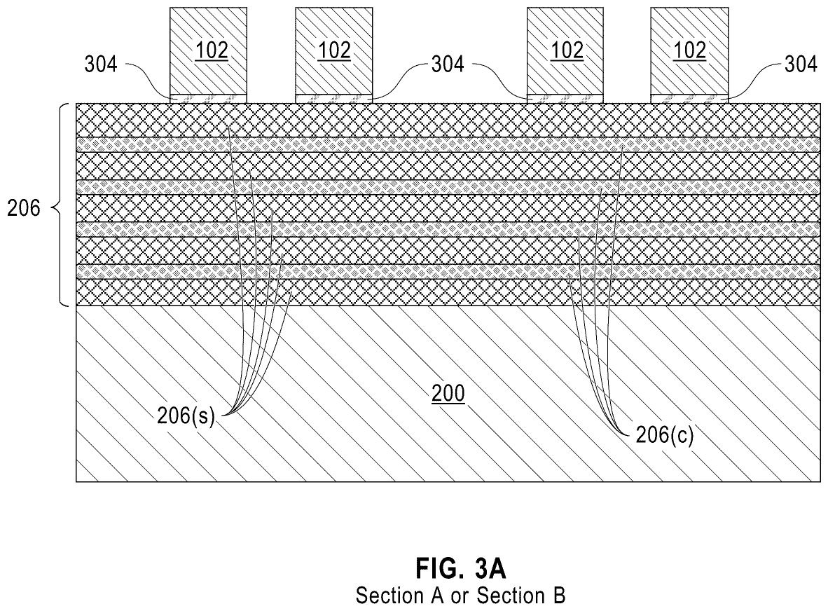

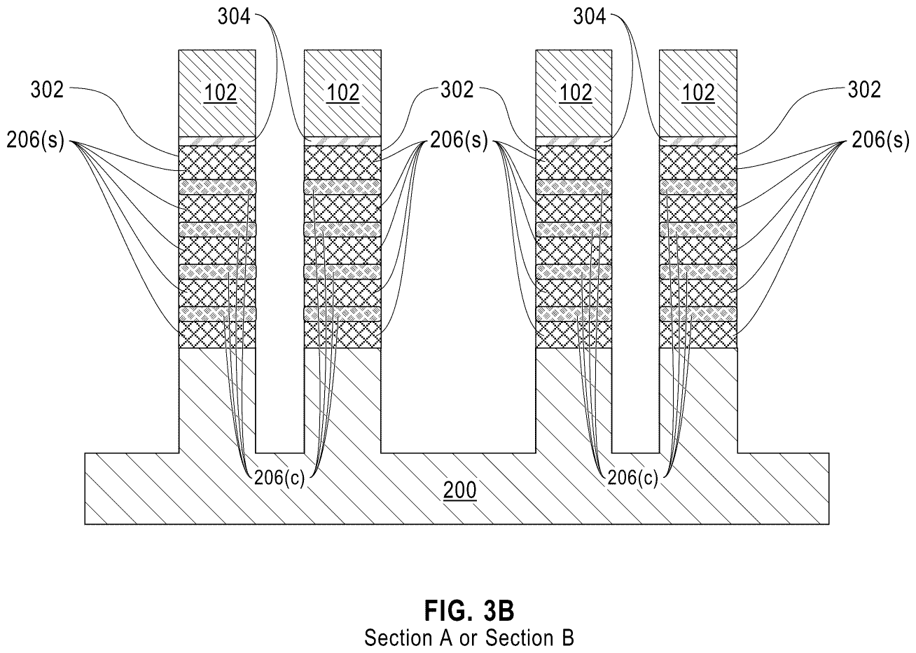

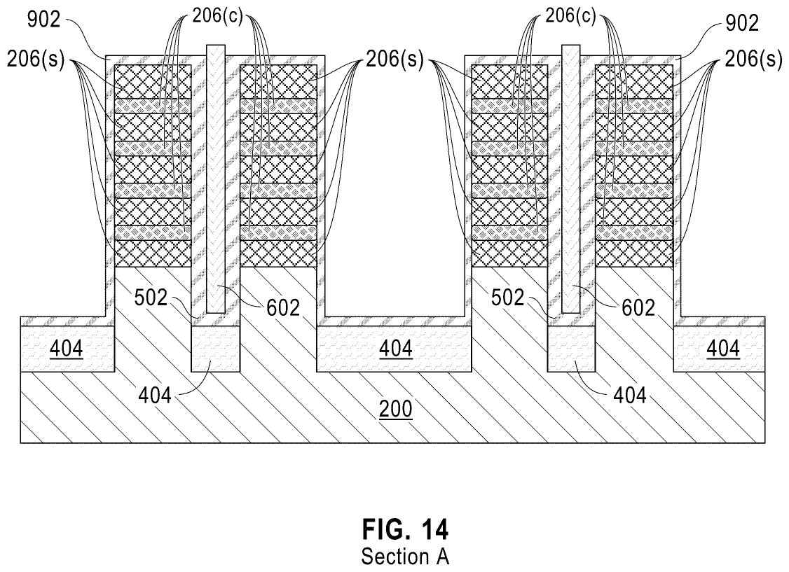

FIGS. 3A through 18 illustrate exemplary structures during different stages of a fabrication process (i.e., intermediate structures of the fabrication process) for forming the exemplary structures shown in FIG. 2A and FIG. 2B (or alternatively FIG. 19). FIGS. 3A through 13 illustrate stages of the fabrication process to show the formation of the vertical and horizontal inner spacer portions 210 and 212 described above with regard to FIG. 2A. FIGS. 14 through 18 illustrate stages of the fabrication process to show the formation of the GAA structure described above with regard to FIG. 2B (or the formation of the alternative GAA structure described below with regard to FIG. 19).

FIGS. 3A through 9 illustrate cross sectional views of exemplary structures, through cut B-B along an edge of the gate structure 104 or through cut A-A along a middle of the gate structure 104 of the device layout in FIG. 1. That is, the cross sectional views shown in FIGS. 3A through 9 are the same through either cut B-B or through cut A-A. However, for simplification purposes, a single figure is used to show the cross sectional views through cut B-B and cut A-A for each of FIGS. 3A through 9.

FIGS. 3A and 3B are used together to illustrate a fin patterning stage of the fabrication process for forming the exemplary structures shown in FIGS. 2A and 2B.

FIG. 3A illustrates a cross sectional view of an exemplary structure, through cut B-B along an edge of the gate structure 104 or cut A-A along a middle of the gate structure 104 of the device layout in FIG. 1, prior to a fin patterning stage of a fabrication process for forming the exemplary structures shown in FIG. 2A and FIG. 2B. As shown in FIG. 3A, the exemplary structure includes a plurality of semiconductor material nanosheets 206 stacked vertically on the substrate 200. Each vertically stacked semiconductor material nanosheet 206 represents a layer of the vertical stack with the layers including alternating sacrificial semiconductor material nanosheets 206(s) and semiconductor material nanosheets 206(c). As further shown in FIG. 3A, a thin insulating gate oxide layer 304 is formed between the active areas 102 and the semiconductor material nanosheets 206.

FIG. 3B illustrates a cross sectional view of an exemplary structure, through cut B-B or cut A-A of the device layout in FIG. 1, after the fin patterning stage of the fabrication process for forming the exemplary structures shown in FIG. 2A and FIG. 2B. As shown in FIG. 3B, portions of the substrate 200 and the semiconductor material nanosheets 206 are removed (e.g., etched) to form the two pairs of fins 302, each fin pair having two adjacent fins 302. Accordingly, trenches are formed (e.g., etched into the substrate 200 and the semiconductor material nanosheets 206) between each pair of adjacent fins 302 of a fin pair and a larger trench is formed between the fin pairs. Each fin 302 includes the vertically stacked semiconductor material nanosheets 206, each including the alternating sacrificial semiconductor material nanosheets 206(s) and semiconductor material nanosheets 206(c). As further shown in FIG. 3B, the thin insulating gate oxide layer 304 is formed between the active areas 102 and the semiconductor material nanosheets 206 of each fin 302.

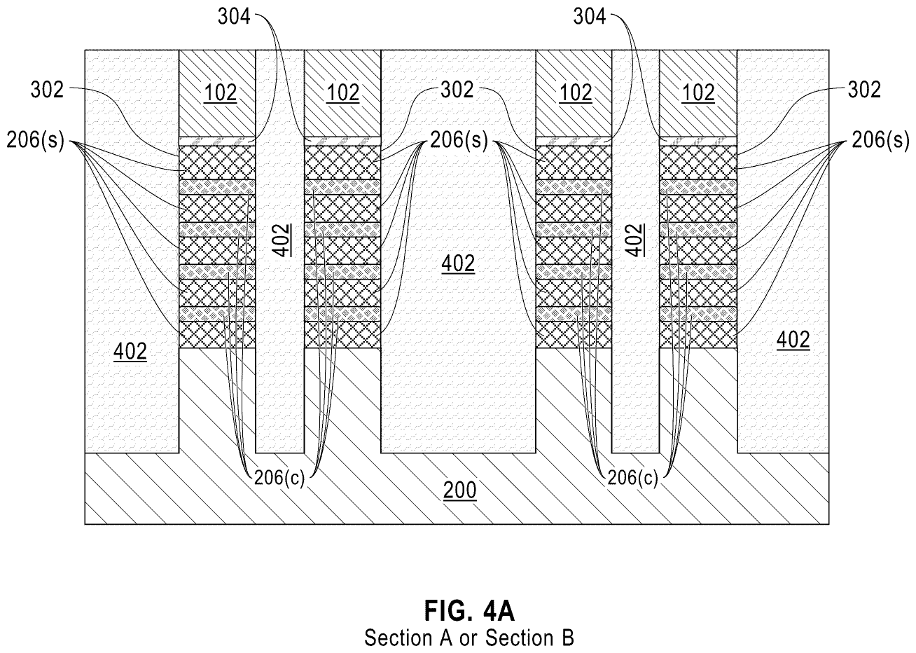

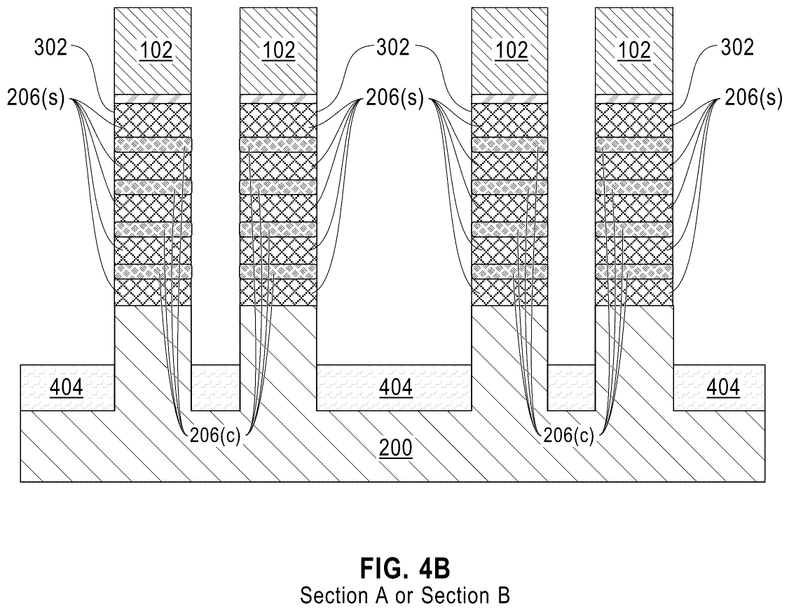

FIGS. 4A and 4B illustrate a shallow trench isolation (STI) layer forming stage of the fabrication process for forming the exemplary structures shown in FIG. 2A and FIG. 2B.

FIG. 4A illustrates a cross sectional view of an exemplary structure, through cut B-B or cut A-A of the device layout in FIG. 1, during a first part of the STI forming stage of the fabrication process for forming the exemplary structures shown in FIG. 2A and FIG. 2B. As shown in FIG. 4A, the trenches formed during the fin patterning stage are filled with a dielectric oxide material 402, which is used to prevent current leakage between adjacent semiconductor components.

FIG. 4B illustrates a cross sectional view of an exemplary structure, through cut B-B or cut A-A of the device layout in FIG. 1, during a second part of the STI forming stage of the fabrication process for forming the exemplary structures shown in FIG. 2A and FIG. 2B. As shown in FIG. 4A, a portion of the oxide material 402 shown in FIG. 4A is removed (e.g., etched) to reveal the STI layer 404 (corresponding to STI layer 214 in FIGS. 2A and 2B).

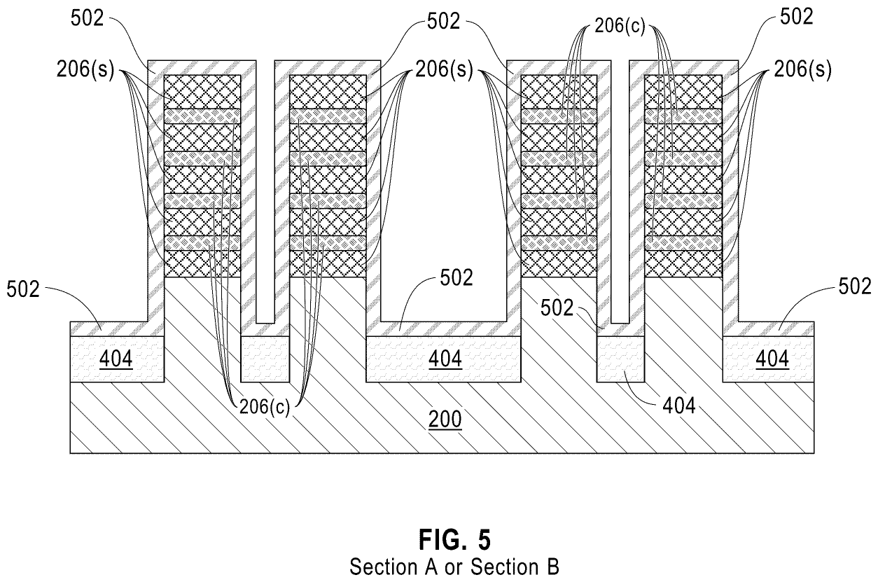

FIG. 5 illustrates a cross sectional view of an exemplary structure, through cut B-B or cut A-A of the device layout in FIG. 1, after a first dielectric layer deposition stage of the fabrication process for forming the exemplary structures shown in FIG. 2A and FIG. 2B.

The active areas 102 shown in FIGS. 4A and 4B are etched away and first dielectric layer 502, composing dielectric material different from the oxide material 402 of the STI layer 404, is deposited on the STI layer 404 to form first dielectric layer 502 as shown in FIG. 5.

The thickness of the first dielectric layer 502 includes a thickness range of about 4 nm to about 8 nm. As described in more detail below, portions of the first dielectric layer 502 are removed from the structure. Accordingly, the thickness of the first dielectric layer 502 is determined based on the eventual thickness used for the gate structure in lieu of the high-k dielectric material and the WFM.

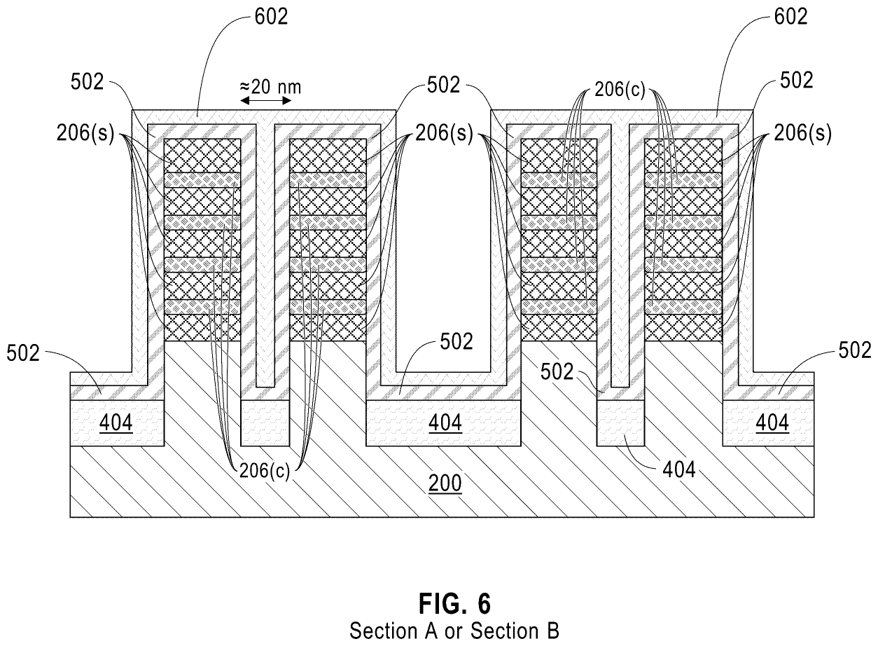

FIG. 6 illustrates a cross sectional view of an exemplary structure, through cut B-B or cut A-A of the device layout in FIG. 1, after a second dielectric layer deposition stage of the fabrication process for forming the exemplary structures shown in FIG. 2A and FIG. 2B. As shown in FIG. 6, a second dielectric layer 602 (corresponding to the dielectric pillar 208 in FIG. 2A) is deposited on the first dielectric layer 502. The material of the second dielectric layer 602 is compositionally different from the material of first dielectric layer 502, while including complimentary etch properties to the material of the first dielectric layer 502.

For example, if the first dielectric layer 502 is composed of silicon oxide, then the second dielectric layer 602 can be composed of silicon nitride. That is, the first dielectric layer 502, composed of silicon oxide, is compositionally different from the second dielectric layer 602 composed of silicon nitride. In addition, the etch properties (e.g., etch rate) of the second dielectric layer 602, composed of silicon nitride, are complimentary to the first dielectric layer 502 such that a substantial thickness the first dielectric layer 502, composed of silicon nitride, is not etched away during the etching of the second dielectric layer 602.

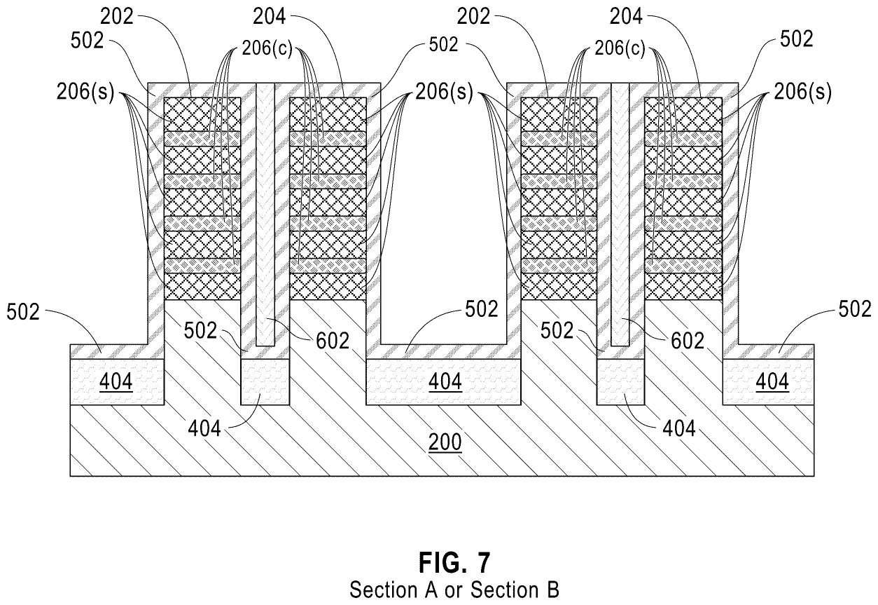

FIG. 7 illustrates a cross sectional view of an exemplary structure, through cut B-B or cut A-A of the device layout in FIG. 1, after a first dielectric layer etching stage of the fabrication process for forming the exemplary structures shown in FIG. 2A and FIG. 2B. Portions of the second dielectric layer 602 are etched away such that the vertical portions of the second dielectric layer 602 shown in FIG. 7, formed between edges of the first dielectric layer 502 in the trenches between the semiconductor channel regions 202 and 204, remain on the structure. In addition, due to the complimentary etch properties of the material of the second dielectric layer 602 to the material of the first dielectric layer 502, the first dielectric layer 502 has not been etched away (e.g., a substantial thickness of the first dielectric layer 502 has not been etched away) during the etching of the second dielectric layer 602.

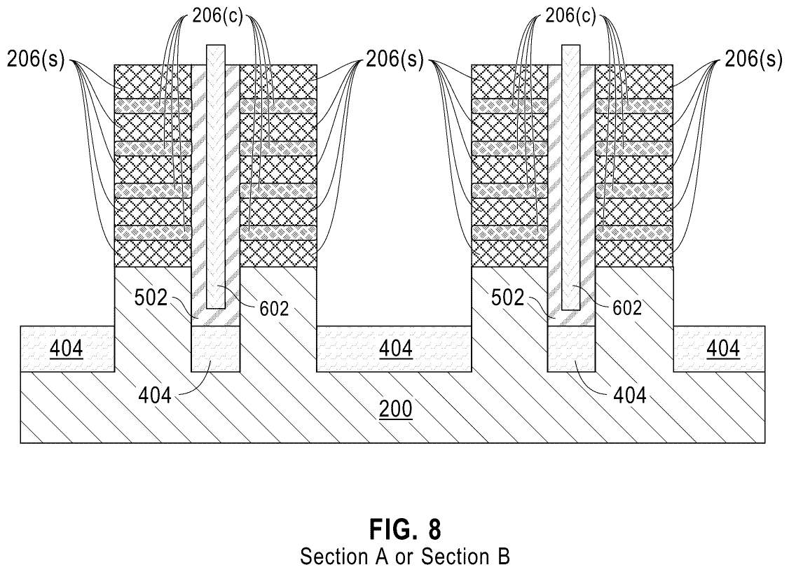

FIG. 8 illustrates a cross sectional view of an exemplary structure, through cut B-B or cut A-A of the device layout in FIG. 1, after a second dielectric layer etching stage of the fabrication process for forming the exemplary structures shown in FIG. 2A and FIG. 2B. Portions of the first dielectric layer 502 are etched away (e.g., using wet chemical etching) such that other portions of the first dielectric layer 502 shown in FIG. 8, formed between the vertical portions of the second dielectric layer 602 and edges of walls of the semiconductor channel regions 202 and 204 remain on the structure. Also, top portions 602(t) of the second dielectric layer 602, extending above a top edge of the portions of the first dielectric layer 502, have not been etched away during the etching of the first dielectric layer 502.

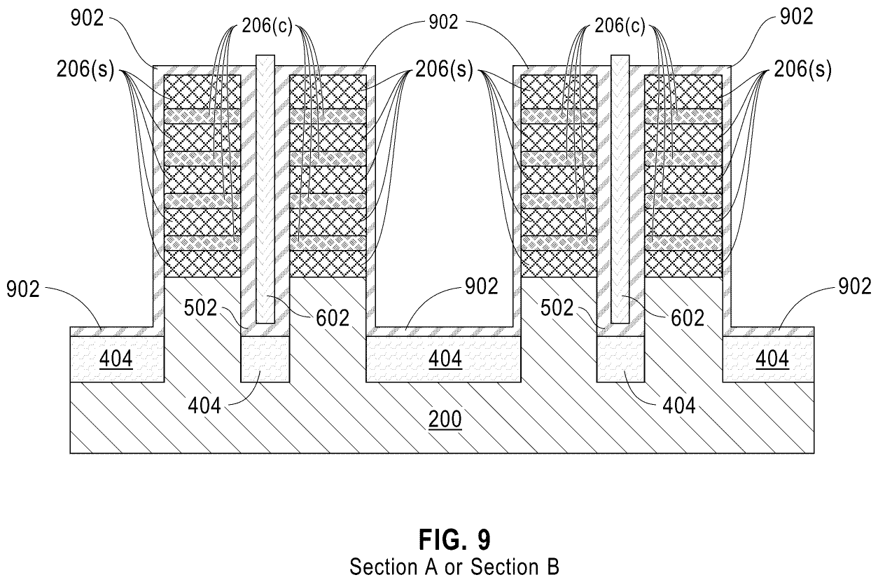

FIG. 9 illustrates a cross sectional view of an exemplary structure, through cut B-B or cut A-A of the device layout in FIG. 1, after performing a gate enabling oxide layer deposition stage of the fabrication process for forming the exemplary structures shown in FIG. 2A and FIG. 2B. As shown in FIG. 9, a gate enabling dielectric layer 902 (corresponding to gate enabling dielectric layer 216 in FIG. 2A), which has a thickness less than the thickness of the portions of the first dielectric layer 502 remaining on the structure, is deposited at the regions where the portions of the first dielectric layer 502 were etched away during the first dielectric layer etching stage.

As described above, the gate structures 104 shown in FIG. 1 include gate spacers (located toward the left and right edges of each of the gate structures 104) and dummy gates (formed at a middle portion, between the gate spacers, of each of the gate structures 104). FIGS. 10A and 10B illustrate cross sectional views of the exemplary structure of FIG. 1, after performing a dummy gate formation stage of the fabrication process.

FIGS. 10A, 11A, 12A and 13A illustrate cross sectional views of exemplary structures, through cut B-B along a gate spacer 1002 of the gate structure 104 shown in the middle of the device layout of FIG. 1, during different stages of the fabrication process for forming the exemplary structure shown in FIG. 2A. FIGS. 10B, 11B, 12B and 13B illustrate cross sectional views of the exemplary structures, through cut A-A along a dummy gate 1004 of the middle gate structure 104 shown in FIG. 1, during different stages of the fabrication process for forming the exemplary structure shown in FIG. 2B.

Gate spacer 1002, shown in FIGS. 10A, 11A, 12A and 13A, is composed of a dielectric material. Illustrative examples of gate dielectric materials are described above. The composition of the gate spacer 1002 is, for example, the same as the composition of the second dielectric layer 602. Alternatively, the composition of the gate spacer 1002 can be different from the composition of the second dielectric layer 602 (e.g., the gate spacer 1002 can be composed of Si3N4 and the second dielectric layer 602 can be composed of SiBCN. or vice versa). The composition of the gate spacer 1002 includes etch properties which are complimentary to the gate enabling dielectric layer 902. That is, the etch properties (e.g., etch rate) of gate spacer 1002 are such that a substantial thickness of the STI layer 404 is not etched away during the etching of the gate spacer 1002. Dummy gate 1004, shown in FIGS. 10B, 11B, 12B and 13B, is for example composed of polysilicon.

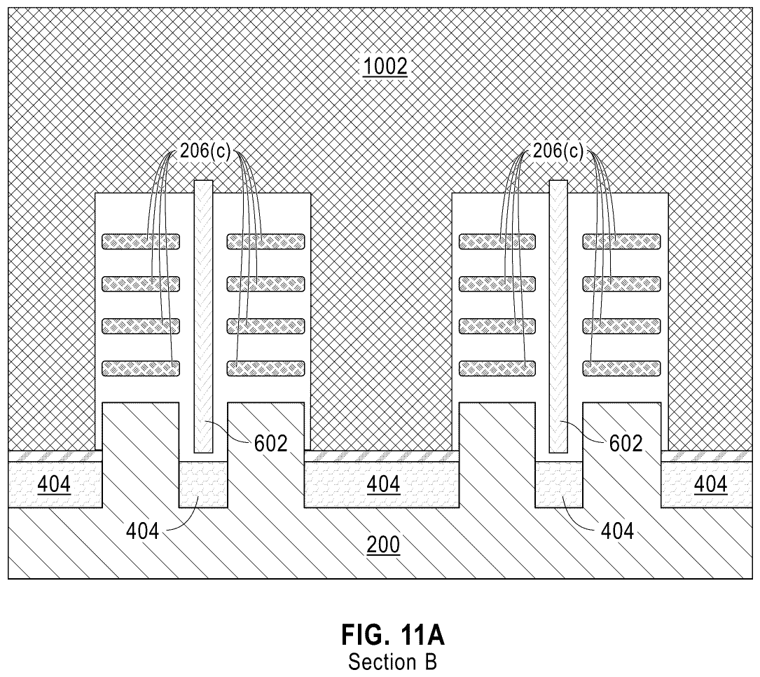

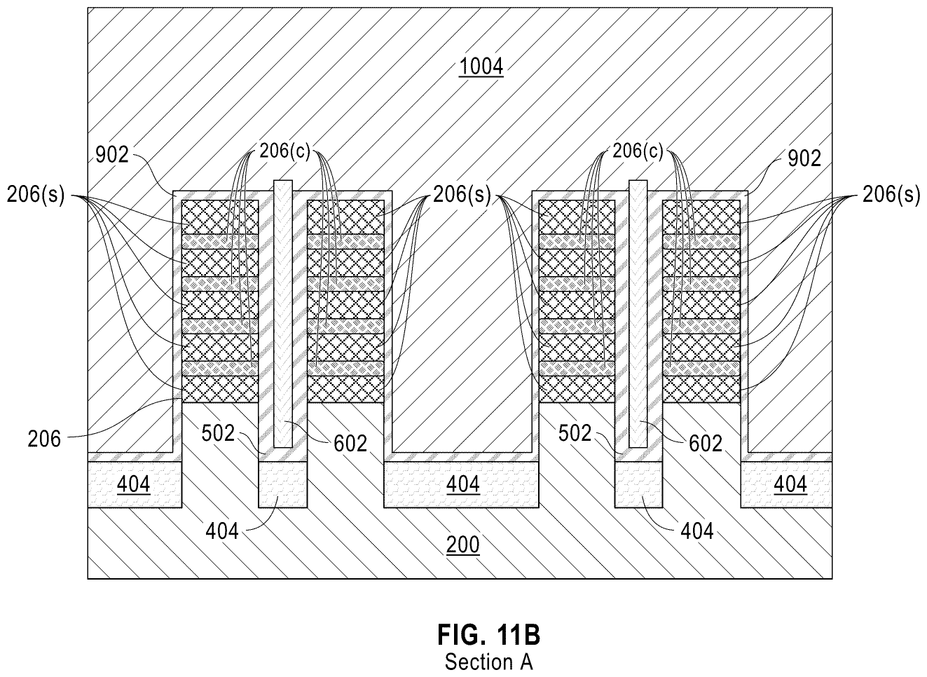

After the dummy gates are formed, an indenting (i.e., partially etching) stage of the fabrication process is performed. FIGS. 10A through 11B are used to illustrate the indenting of sacrificial semiconductor material and the gate enabling oxide layer during the indenting stage of the fabrication process.

FIG. 10A illustrates a cross sectional view of an exemplary structure, through cut B-B of the device layout in FIG. 1, after the dummy gates are formed and prior to performing a sacrificial semiconductor material indenting stage of the fabrication process for forming the exemplary structure shown in FIG. 2A. FIG. 10B illustrates a cross sectional view of the exemplary structure of FIG. 2B, through cut A-A of the device layout in FIG. 1, after the dummy gate structure is formed and prior to performing the sacrificial semiconductor material indenting stage of the fabrication process for forming the exemplary structure shown in FIG. 2B.

FIG. 11A illustrates a cross sectional view of an exemplary structure, through cut B-B of the device layout in FIG. 1, after performing the sacrificial semiconductor material indenting stage of the fabrication process for forming the exemplary structure shown in FIG. 2A. FIG. 11B illustrates a cross sectional view of the exemplary structure of FIG. 2B, through cut A-A of the device layout in FIG. 1, after performing the sacrificial semiconductor material indenting stage of the fabrication process for forming the exemplary structure shown in FIG. 2B.

During the indenting stage of the fabrication process, each of the sacrificial semiconductor material nanosheets 206(s) of the vertically stacked semiconductor material nanosheets 206 are partially etched (i.e., removed) utilizing a material removal process. For example, as shown in FIG. 11A, the sacrificial semiconductor material nanosheets 206(s) are etched (i.e., removed) from the vertically stacked semiconductor material nanosheets 206 along the middle gate spacer of the gate structure 104 shown in FIG. 1. However, as shown in FIG. 11B, the sacrificial semiconductor material nanosheets 206(s) are not etched (i.e., not removed) from the vertically stacked semiconductor material nanosheets 206 along the dummy gate of the middle gate structure 104 shown in FIG. 1. That is, the sacrificial semiconductor material nanosheets 206(s) are indented with respect to the dummy gate of the middle gate structure 104, resulting in each semiconductor material nanosheet 206(c) being suspended from the vertically stacked semiconductor material nanosheets along the dummy gate of the middle gate structure 104.

In addition, as shown in FIG. 11A, portions of the gate enabling dielectric layer 902 are also etched (i.e., removed) from the vertically stacked semiconductor material nanosheets 206 along the middle gate spacer of the gate structure 104 shown in FIG. 1. However, as shown in FIG. 11B, the gate enabling dielectric layer 902 is not etched (i.e., not removed) from the vertically stacked semiconductor material nanosheets 206 along the dummy gate of the middle gate structure 104 shown in FIG. 1.

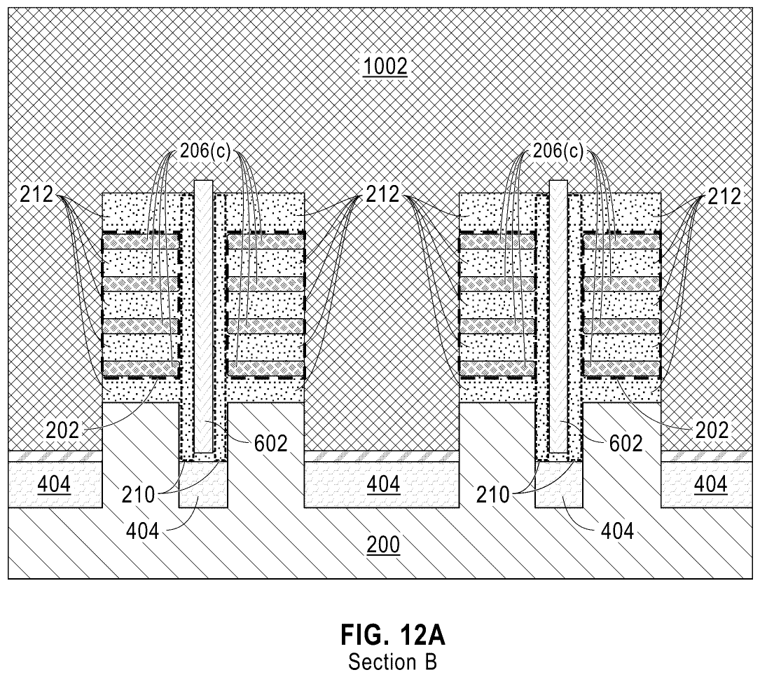

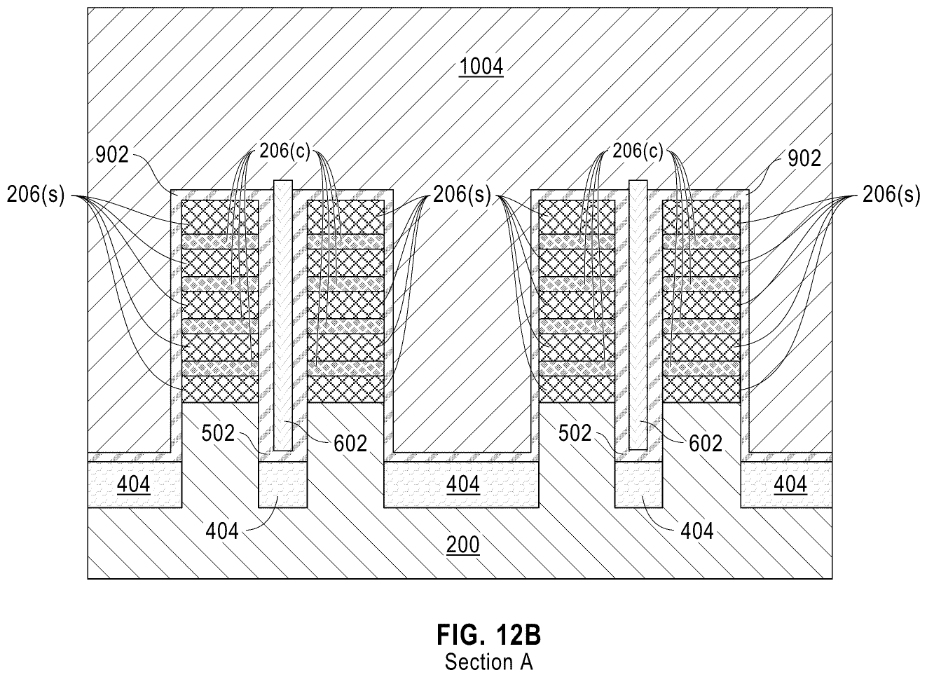

FIGS. 12A and 12B illustrate the results of an inner spacer portion deposition stage of the fabrication process for forming the exemplary structures shown in FIG. 2A and FIG. 2B.

FIG. 12A illustrates a cross sectional view of an exemplary structure, through cut B-B of the device layout in FIG. 1, after performing an inner spacer portion deposition stage of the fabrication process for forming the exemplary structure shown in FIG. 2A. As shown in FIG. 12A, inner spacer portions 210 and 212 are deposited in the regions previously occupied by the sacrificial semiconductor material nanosheets 206(s) and the gate enabling dielectric layer 902 which were partially etched from the vertically stacked semiconductor material nanosheets 206 during the indenting stage of the fabrication process.

For example, as shown in FIG. 12A, inner spacer portions include vertical inner spacer portions 210 extending vertically above the substrate 200 and located between the second dielectric layer 602 (i.e., the dielectric pillar 208 in FIG. 2A) and inner edges of the suspended semiconductor material nanosheets 206(c) (i.e., between inner edges of the suspended semiconductor material nanosheets 206(c) of the first semiconductor channel region 202 and the dielectric pillar 208 and between inner edges of the suspended semiconductor material nanosheets 206(c) of the second semiconductor channel region 204 and the dielectric pillar 208). That is, the vertical inner spacer portions 210 are deposited in regions previously occupied by the gate enabling dielectric layer 902.

The inner spacer portions also include horizontal inner spacer portions 212 located between the suspended semiconductor material nanosheets 206(c) of semiconductor channel regions 202 and 204 as well as above each semiconductor channel region (i.e., above the top suspended semiconductor material nanosheet 206(c) in each semiconductor channel region 202 and 204) and below each semiconductor channel region (i.e., below the bottom suspended semiconductor material nanosheets 206(c) in each semiconductor channel region 202 and 204).

The vertical and horizontal inner spacer portions 210 and 212 are composed of a dielectric material which is compositionally different from the dielectric material of the first dielectric layer 502 and the gate spacer 1002. In addition, the material of the vertical and horizontal inner spacer portions 210 and 212 includes etch properties which are complimentary to the first dielectric layer 502 and the gate enabling dielectric layer 902.

FIG. 12B illustrates a cross sectional view of an exemplary structure, through cut A-A of the device layout in FIG. 1, after performing the inner spacer portion deposition stage of the fabrication process for forming the exemplary structure shown in FIG. 2B. As described above, the sacrificial semiconductor material nanosheets 206(s) and the gate enabling dielectric layer 902 are not etched (i.e., not removed) from the vertically stacked semiconductor material nanosheets 206 along the dummy gate of the middle gate structure 104 shown in FIG. 1. Accordingly, as shown in FIG. 12B, the vertical and horizontal inner spacer portions 210 and 212 are not present because the vertical and horizontal inner spacer portions 210 and 212 are only deposited in the regions previously occupied by the sacrificial semiconductor material nanosheets 206(s) and the gate enabling dielectric layer 902 which were partially etched from the vertically stacked semiconductor material nanosheets 206 during the indenting stage of the fabrication process.

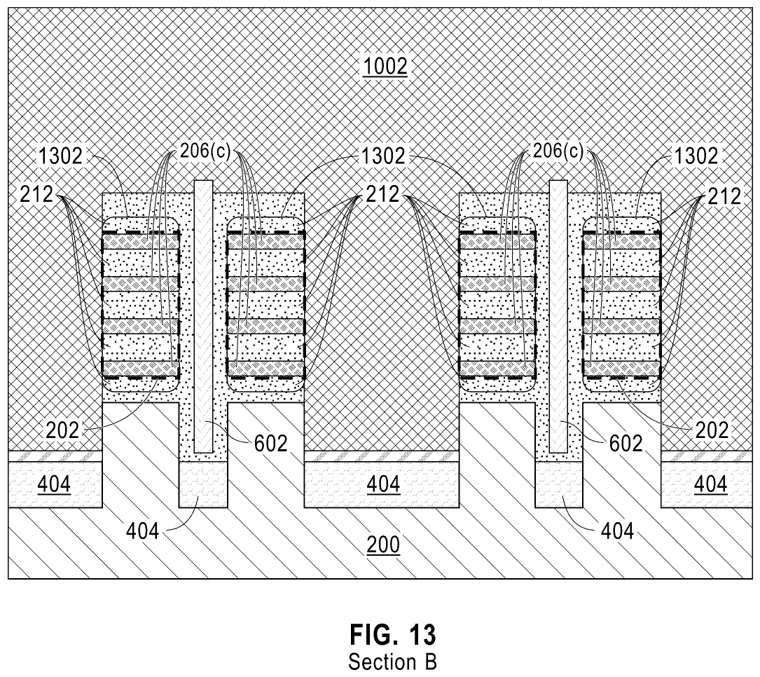

Next, an epitaxy (EPI) growth stage of the fabrication process is performed. FIG. 13 illustrates a cross sectional view of an exemplary structure, through a cut, parallel to but to the right of the cut B-B of the device layout in FIG. 1 (e.g., a few nanometers to the right of cut B-B within the structure), along an edge of the middle gate spacer of the gate structure shown in FIG. 1, after performing an epitaxy growth stage of the fabrication process for forming the exemplary structure shown in FIG. 2A. As shown in FIG. 13, an EPI layer 1302 is formed on the suspended semiconductor material nanosheets 206(c). The EPI layer 1302 is a thin crystal layer, which can include the same, or different semiconductor material as the suspended semiconductor material nanosheets 206(c). The semiconductor material of the EPI layer 1302 has a higher doping concentration than the material of the suspended semiconductor material nanosheets 206(c).

The EPI layer 1302 enables more efficient electron injection through the semiconductor device. As shown in FIG. 13, the suspended semiconductor material nanosheets 206(c) are still visible through the EPI layer 1302. However, as the cross sectional view moves to the right of the cut B-B in FIG. 1, the suspended semiconductor material nanosheets 206(c) become less visible through the thickness of the EPI layer 1302.

FIGS. 14 through 18 illustrate cross sectional views of exemplary structures, through cut A-A along a dummy gate of the middle gate structure 104 of the device layout shown in FIG. 1. FIGS. 14 through 18 are used to illustrate the formation of the GAA structure (shown in FIG. 2B or alternatively in FIG. 19) of the semiconductor device as a result of performing the stages of the fabrication process now described below.

FIG. 14 illustrates a cross sectional view of an exemplary structure, through cut A-A along a middle portion of the gate structure 104 shown in FIG. 1, after performing a dummy gate etching stage of the fabrication process for forming the exemplary structure shown in FIG. 2B. As shown in FIG. 14, the material (e.g., polysilicon) of the dummy gate 1004 shown in FIGS. 10B, 11B, 12B and 13B has been etched away.

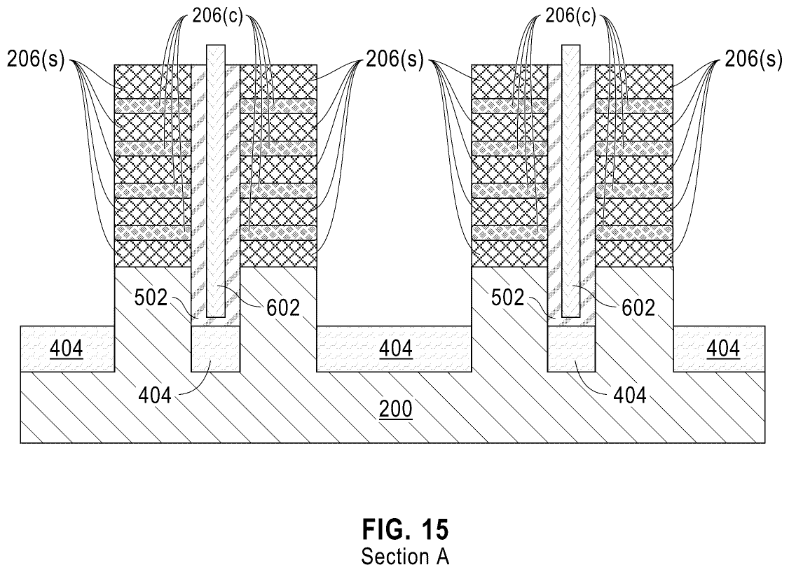

FIG. 15 illustrates a cross sectional view of an exemplary structure, through cut A-A of the device layout in FIG. 1, after performing a gate enabling oxide layer etching stage of the fabrication process for forming the exemplary structure shown in FIG. 2B.

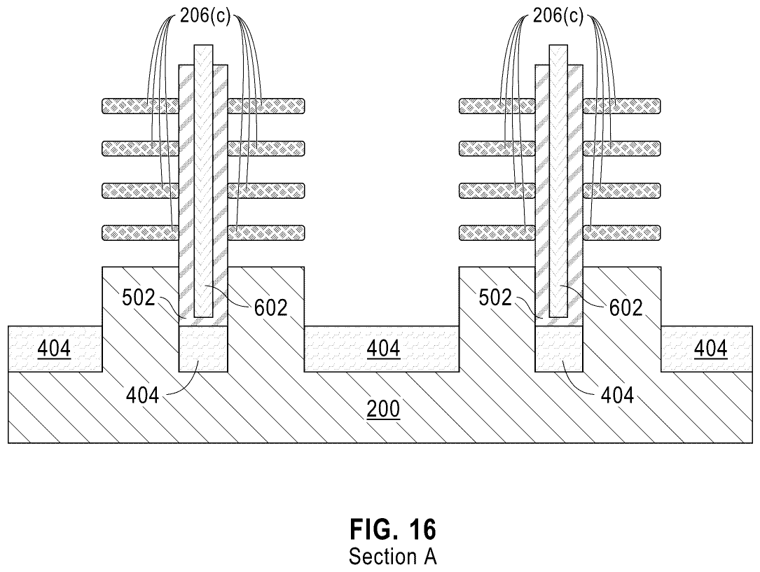

FIG. 16 illustrates a cross sectional view of an exemplary structure, through cut A-A along a middle portion of the gate structure 104 shown in FIG. 1, after performing the sacrificial semiconductor material etching stage of the fabrication process for forming the exemplary structure shown in FIG. 2B. During the sacrificial semiconductor material etching stage of the fabrication process, the sacrificial semiconductor material nanosheets 206(s) along the middle portion of the gate structure 104 (i.e., the sacrificial semiconductor material nanosheets 206(s) that was not previously etched away) is etched (i.e., removed) utilizing a material removal process. For example, as shown in FIG. 16, the sacrificial semiconductor material nanosheets 206(s) shown in FIGS. 10B, 11B and 12B have been etched (i.e., removed) from the structure along the middle gate spacer of the gate structure 104.

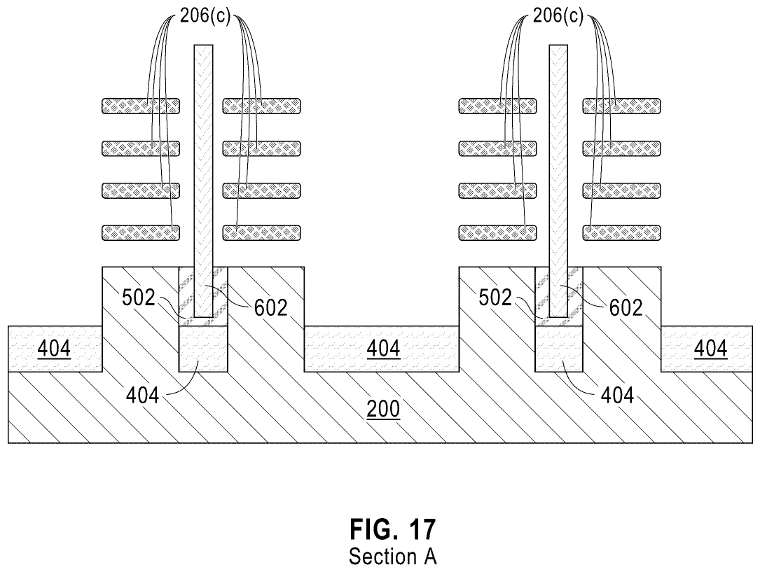

FIG. 17 illustrates a cross sectional view of an exemplary structure, through cut A-A along a middle portion of the gate structure shown in FIG. 1, after performing a first dielectric layer etching stage of the fabrication process for forming the exemplary structure shown in FIG. 2B. During the first dielectric layer 502 etching stage of the fabrication process, portions of the first dielectric layer 502 are etched (i.e., removed) from the structure along the middle portion of the gate structure 104. For example, as shown in FIG. 17, portions of the first dielectric layer 502 shown in FIGS. 10B, 11B and 12B have been etched (i.e., removed) from the structure along the middle gate spacer of the gate structure 104, with the portions of the first dielectric layer 502 shown in FIG. 16 remaining in the structure (i.e., the bottom portions of the first dielectric layer 502 in the trenches.

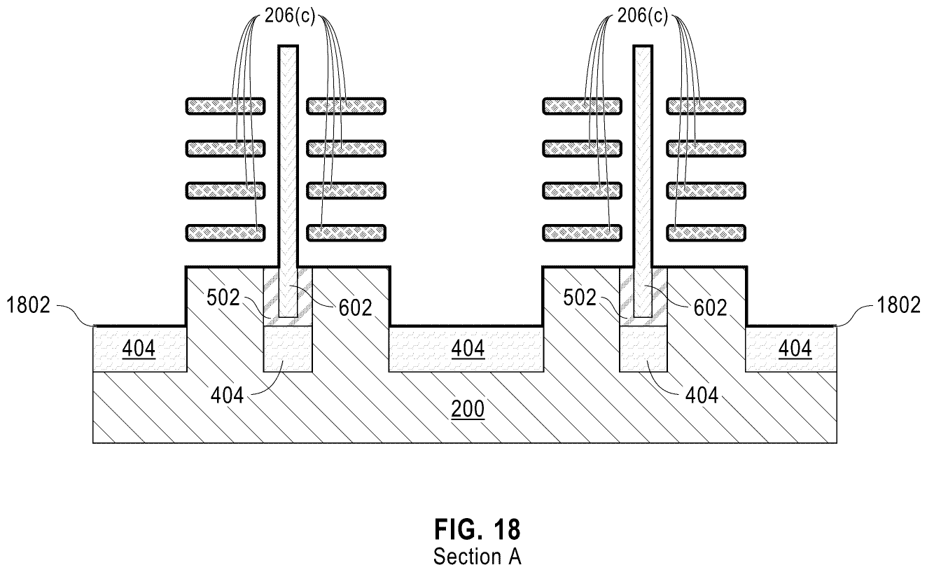

FIG. 18 illustrates a cross sectional view of an exemplary structure, through cut A-A along the middle portion of the gate structure shown in FIG. 1, after performing a high-k deposition stage of the fabrication process for forming the exemplary structure shown in FIG. 2B. As shown in FIG. 18, a high-k dielectric material 1802 is deposited on the substrate 200, the STI layer 404, the semiconductor material nanosheets 206(c) and second dielectric layer 602 along the middle portion of the gate structure 104.

FIG. 19 illustrates a cross sectional view of an exemplary structure, through cut A-A along the middle portion of the gate structure shown in FIG. 1, after performing a WFM replacement gate cut forming stage of the fabrication process. The exemplary structure shown in FIG. 19 illustrates another example of a GAA structure formed on 4 sides (i.e., the top, bottom, left and right) of each of the semiconductor material nanosheets 206(c) shown in FIG. 2A, that can be used in accordance with an embodiment of the present application. That is, FIG. 19 illustrates another example of a structure, alternative to the structure shown in FIG. 2B. As shown in FIG. 19, WFM 1902 is deposited on the STI layer 404, the semiconductor material nanosheets 206(c) and the second dielectric layer 602 along the middle portion of the gate structure 104. In addition, a metal gate material 1904 is deposited on the WFM 1902. The material of the WFM 1902 and the metal gate material 1904 is matched to a polarity of the fork sheet transistor.

The GAA structures shown in FIG. 2B and FIG. 19 are merely examples. Features of the present disclosure can include GAA structures different from those shown in FIG. 2B and FIG. 19, including any number of different types of WFMs and different combinations of WFMs to match the polarity of the material of the WFMs and the metal gate material to the polarity of the fork sheet transistor.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device including:
a pair of fork sheet transistors, each including:
a plurality of vertically stacked, and spaced apart, semiconductor material nanosheets; and
a gate all around (GAA) structure formed on the semiconductor material nanosheets;
a dielectric pillar, composed of a first dielectric material, and located between the pair of fork sheet transistors;
first inner spacer portions, composed of a second dielectric material, located between the dielectric pillar and inner edges of the semiconductor material nanosheets of each fork sheet transistor; and
second inner spacer portions, composed of the second dielectric material, located between each of the semiconductor material nanosheets, above the semiconductor material nanosheets and below the semiconductor material nanosheets.

2. The semiconductor device of claim 1, wherein the first dielectric material and the second dielectric material have a same composition.

3. The semiconductor device of claim 1, wherein the first dielectric material and the second dielectric material have different compositions.

4. The semiconductor device of claim 1, wherein the first inner spacer portions include:
a first vertical inner spacer portion, extending in a vertical direction parallel to the dielectric pillar, and located between a first inner edge of the dielectric pillar and inner edges of the semiconductor material nanosheets of one of the pair of fork sheet transistors; and
a second vertical inner spacer portion, extending in the vertical direction, and located between a second inner edge of the dielectric pillar and inner edges of the semiconductor material nanosheets of another of the pair of fork sheet transistors.

5. The semiconductor device of claim 1, further including:
a substrate; and
a shallow trench isolation (STI) layer deposited on the substrate,
wherein the first inner spacer portions extend, in a vertical direction, from the STI layer.

6. The semiconductor device of claim 1, wherein, for each one of the fork sheet transistors, the second inner spacer portions, include:
first horizontal spacer portions, extending in a horizontal direction perpendicular to the inner edges of the dielectric pillar, and located between each of the semiconductor material nanosheets;
a second horizontal spacer portion, extending in the horizontal direction, and located above a top one of the semiconductor material nanosheets; and
a third horizontal spacer portion, extending in the horizontal direction, and located below a bottom one of the semiconductor material nanosheets.

7. The semiconductor device of claim 1, wherein one of the fork sheet transistors of the pair of fork sheet transistors is an NFET, and another of the fork sheet transistors of the pair of fork sheet transistors is a PFET.

8. The semiconductor device of claim 1, wherein each of the forks sheet transistors is an NFET or each of the forks sheet transistors is a PFET.

9. The semiconductor device of claim 1, wherein the GAA structure includes at least one type of work function metal (WFM) formed directly on the plurality of vertically stacked, and spaced apart semiconductor material nanosheets.

10. A semiconductor device including:
a substrate;
a pair of fork sheet transistors, formed on the substrate, each fork sheet transistor including a semiconductor channel region which includes a plurality of vertically stacked, and spaced apart, semiconductor material nanosheets;
a dielectric pillar, composed of a first dielectric material, and located between the pair of fork sheet transistors;
first inner spacer portions, composed of a second dielectric material, located between the dielectric pillar and each semiconductor channel region; and
second inner spacer portions, composed of the second dielectric material, located between each of the semiconductor material nanosheets, above each semiconductor channel region and below each semiconductor channel region.

11. The semiconductor device of claim 10, wherein the first dielectric material and the second dielectric material have a same composition.

12. The semiconductor device of claim 10, wherein the first dielectric material and the second dielectric material have different compositions.

13. The semiconductor device of claim 10, wherein the first inner spacer portions include:
a first vertical inner spacer portion, extending in a vertical direction parallel to the dielectric pillar, and located between a first inner edge of the dielectric pillar and an inner edge of the semiconductor channel region of one of the pair of fork sheet transistors; and
a second vertical inner spacer portion, extending in the vertical direction, and located between a second inner edge of the dielectric pillar and an inner edge of the semiconductor channel region of another of the pair of fork sheet transistors.

14. The semiconductor device of claim 10, further comprising:
a shallow trench isolation (STI) layer deposited on the substrate,
wherein the first inner spacer portions extend, in a vertical direction, from the STI layer.

15. The semiconductor device of claim 10, wherein one of the fork sheet transistors of the pair of fork sheet transistors is an NFET, and another of the fork sheet transistors of the pair of fork sheet transistors is a PFET.

16. The semiconductor device of claim 10, wherein each of the forks sheet transistors of the pair of transistors is an NFET or each of the forks sheet transistors of the pair of transistors is a PFET.

17. The semiconductor device of claim 10, wherein each fork sheet transistor further includes a gate all around (GAA) structure which surrounds the plurality of vertically stacked, and spaced apart semiconductor material nanosheets.

18. A fork sheet transistor including:
a source region;
a drain region;
a semiconductor channel region including a plurality of semiconductor material nanosheets, separated from each other, and stacked vertically between the source region and the drain region: and
a gate all around (GAA) structure formed on the plurality of semiconductor material nanosheets,
wherein first inner spacer portions, composed of a first dielectric material, are located between an edge of the semiconductor channel region and a dielectric pillar, the dielectric pillar being composed of a second dielectric material and located adjacent the semiconductor channel region, and
second inner spacer portions, composed of the second dielectric material, are located between each of the plurality of semiconductor material nanosheets, above the semiconductor channel region and below the semiconductor channel region.

19. The fork sheet transistor of claim 18, wherein the first dielectric material and the second dielectric material have a same composition.

20. The fork sheet transistor of claim 18. wherein the first dielectric material and the second dielectric material have different compositions.
